(19) United States
(12) Patent Application Publication
(10) Pub. No.: US 2026/0283010 A1
(43) Pub. Date: Sep. 17, 2026

(54) MOUNTING CRYSTAL RESONATOR OVER INDUCTOR IN AN INTEGRATED CIRCUIT PACKAGE

(71) Applicant: Microchip Technology Incorporated, Chandler, AZ (US)

(72) Inventors: Slobodan Milijevic, Ottawa (CA); John Kirby, San Jose, CA (US); Isabella Ikadara, Chandler, AZ (US); Denis Verreault, Gatineau (CA); Abbas Tariq, Ottawa (CA)

(73) Assignee: Microchip Technology Incorporated, Chandler, AZ (US)

(21) Appl. No.: 19/078,721

(22) Filed: Mar. 13, 2025

(51) Int. Cl. H01L 25/16; H01L 23/00; H01L 23/64

(52) U.S. Cl. CPC H10W 90/00; H10W 44/501; H10W 72/865; H10W 90/734; H10W 90/758

(57) ABSTRACT

Some examples of the teachings herein include a system comprising: a silicon die including an inductor element; a crystal connected to the silicon die by bonding wires; and a non-conductive spacer between the silicon die and the crystal; wherein the non-conductive spacer has a thickness defining a distance between the silicon die and the crystal, the distance selected to reduce an effect of the crystal on a magnetic flux of the inductor.

### PRIORITY

This application claims priority to U.S. Provisional Patent Application No. 63/708,537 filed Oct. 17, 2024, the contents of which are hereby incorporated in their entirety.

### TECHNICAL FIELD

The present disclosure relates to integrated circuits (IC). Various examples of the teachings herein include system and/or methods for clock synthesizer ICs.

### BACKGROUND

Integrated circuits (IC) are small electronic systems with multiple connected electronic components. Some ICs are called microchips or computer chips. They may include a multitude of transistors, resistors, and/or capacitors on a silicon substrate (or other layers) in the IC. The ongoing development of ICs requires decreasing size and cost while increasing performance and predictability.

Clock synthesizer ICs typically include a crystal resonator or a crystal oscillator for use as a stable reference with a fixed frequency. The output from the crystal resonator or oscillator may be used, in turn, as the input for a Phase Locked Loop (PLL) to create a required output frequency. A typical high-performance PLL uses an LC-based (inductor/capacitor) Voltage Controlled Oscillator (VCO). The inductor may be a loop or a spiral on top of metal layers disposed on the silicon substrate.

In some applications, enclosing a metal layer inside the IC may interfere with the performance of the inductor. Such interference may affect the expected frequency of a VCO and/or reduce an LC quality factor.

At the same time, embedding the crystal resonator or oscillator in the IC may affect the size, performance, predictability, and/or cost of the IC.

### SUMMARY

The teachings of the present disclosure include IC packages with a crystal oscillator and/or resonator and an inductor with reduced interference between the two. For example, some examples include a system comprising: a silicon die including an inductor element; a crystal connected to the silicon die by bonding wires; and a non-conductive spacer between the silicon die and the crystal; wherein the non-conductive spacer has a thickness defining a distance between the silicon die and the crystal, the distance selected to reduce an effect of the crystal on a magnetic flux of the inductor.

As another example, some embodiments of the teachings herein include a An integrated circuit package comprising: a silicon die including an inductor element; a non-conductive spacer with a first side attached to the silicon die above the inductor element; a crystal attached to a second side of the non-conductive spacer opposite the first side; bonding wires connecting the crystal to the silicon die; and an encapsulation surrounding the crystal and the spacer; wherein the non-conductive spacer has a thickness between the silicon die and the crystal, the thickness selected to reduce an effect of the crystal on a magnetic flux of the inductor.

### BRIEF DESCRIPTION OF THE DRAWINGS

FIG. 1 is a drawing showing a first prior art IC package in a top view;

FIG. 2 is a drawing showing a second prior art IC package in a side view;

FIG. 3 is a drawing showing an example IC package incorporating teachings of the present disclosure;

FIG. 4 is a drawing showing portions of an example IC package incorporating teachings of the present disclosure;

FIG. 5A is a drawing showing a geometric equivalent of a rectangular trace-based inductor from a top view;

FIG. 5B is a drawing showing the same geometric equivalent from a front view;

FIG. 6 is a mathematical figure with calculations for a magnetic field;

FIG. 7 is a mathematical figure with calculations for an integrated magnetic field;

FIG. 8 is a graph showing normalized inductance versus distance; and

FIG. 9 is a graph showing VCO frequency versus distance.

### DETAILED DESCRIPTION

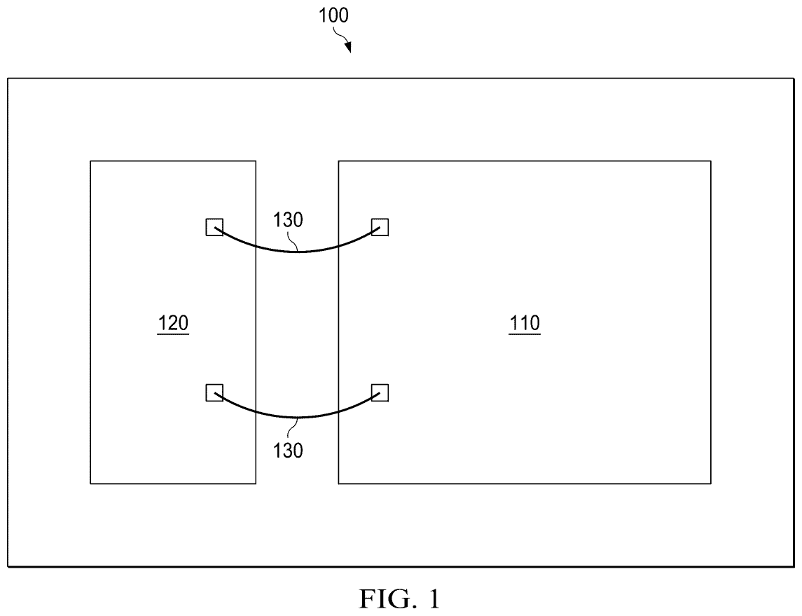

A typical clock generator die for an IC is relatively small, requiring only a limited footprint for the entire IC package including such a clock generator die. Usually, the inductor is the element with the largest footprint in the clock generator circuit. For this reason, placing a crystal oscillator/resonator in a vertical stack over or under the inductor element will result in an overlap between the crystal and the inductor element, producing potential interference and the concomitant reduction in performance. Some attempts to resolve this issue include placing the crystal beside the clock generator die and connecting the crystal to the clock generator die with bonding wires. In practice, this design may roughly double the resulting footprint of the IC package. FIG. 1 is a picture showing the top view of a prior art IC package 100 including a silicon die 110 and a crystal oscillator/resonator 120 connected by wire bonds 130.

A crystal oscillator typically uses a piezoelectric crystal serving as a frequency-selective element. A common example includes a quartz crystal. Some other examples include polycrystalline ceramics. The frequency of the crystal oscillator may be used as a time keeper for other elements in a circuit or IC package. For example, radio transmitters and receivers may use a crystal oscillator to stabilize frequencies. Applying a voltage to a crystal oscillator causes the crystal to change shape. Removing the voltage allows the crystal to elastically return to its original shape. At the same time, the crystal generates a measurable voltage. The oscillation is at a stable resonant frequency with reduced energy loss on each cycle in comparison to an RLC circuit.

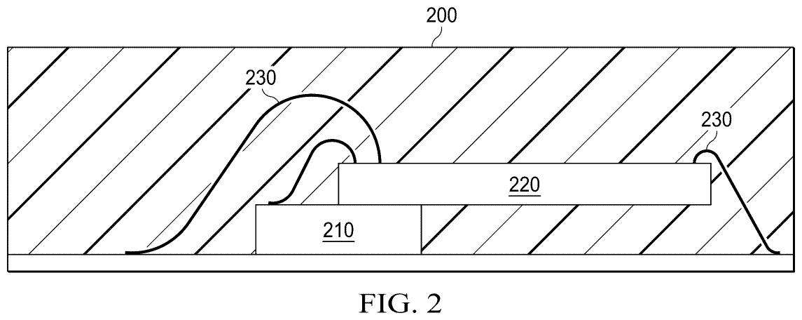

Some attempts to include a crystal in an IC package while reducing the resulting footprint in comparison to the example of FIG. 1 include mounting the crystal at the bottom of the silicon die, arranged so one side of the crystal resonator is not covered by the silicon die, namely the side with crystal pads. In practice, this still increases the footprint of the IC package and requires longer bonding wires. FIG. 2 is a drawing of a prior art IC package 200 including a silicon die 210 and a crystal oscillator/resonator 220 connected by wire bonds 230.

Mounting a crystal oscillator/resonator inside an IC package, but on top of a non-conductive spacer separates the oscillator/resonator from the inductor element. In practice, this design may reduce or eliminate the effect on the resulting footprint of the IC compared to the options described above without interfering with the performance of the inductor element. The IC package need not be any wider side-to-side to accommodate the crystal and there is minimal effect on the length of the bonding wires.

The thickness (in the dimension of the height of the IC) of a non-conductive spacer will, however, drive a resulting height for the IC package. A minimum thickness may be chosen to provide effective separation between the crystal oscillator/resonator and the inductor element and, therefore, allow the smallest height for the IC package.

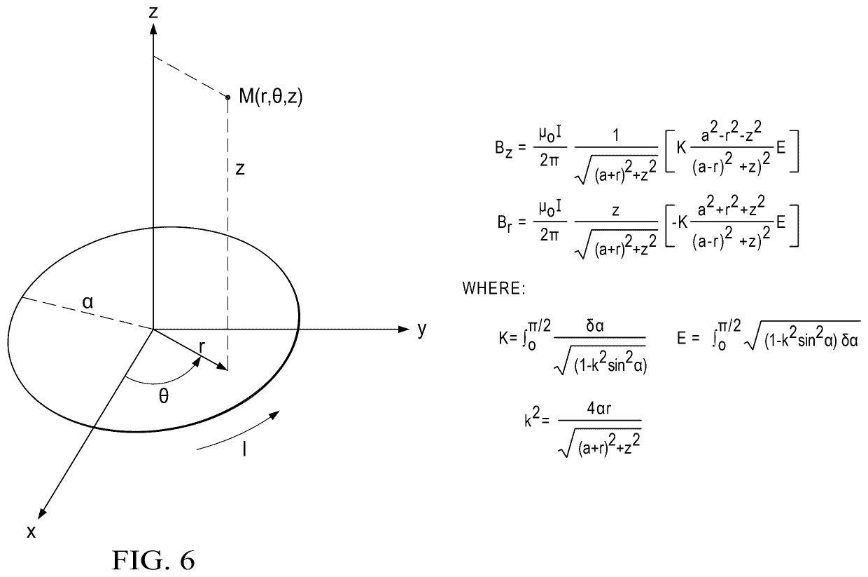

To calculate the effect of the thickness, d, of the spacer, one may model the inductor as a circular conductor with an area equal to the area of the actual inductor. In practice, the actual inductor may be square, hexagonal, or octagonal with long leads affecting the total inductance. The magnetic field may be calculated at an arbitrary point M(r, θ, z) as shown in FIG. 6:

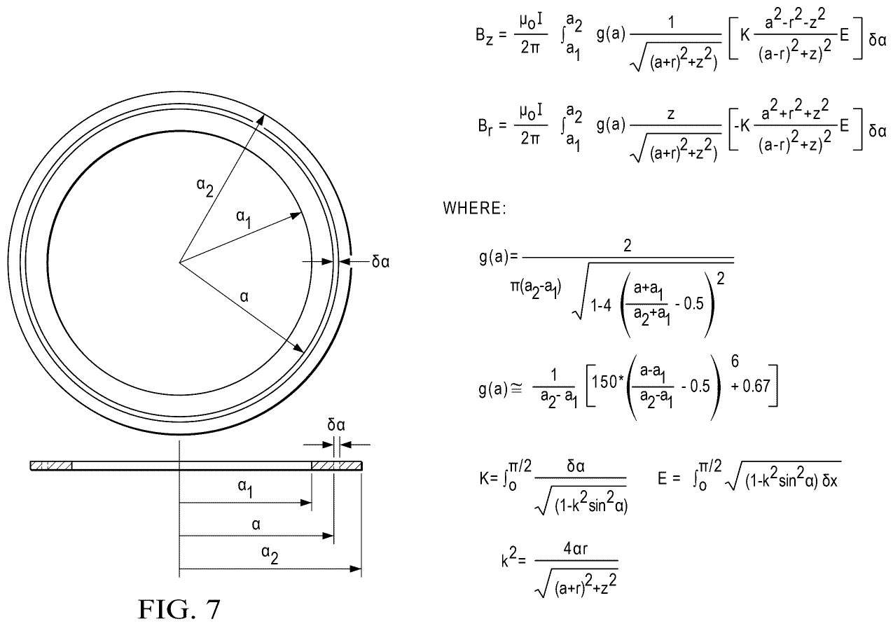

Due to rotational symmetry, the angular component drops out because the magnetic field is not a function of the angle θ. The equations shown provide the magnetic field in terms of r and z, where K and E are complete elliptic integrals of the first and second kind, respectively. These equations hold for the magnetic field of a thin circular wire. An IC inductor is not a think wire, but a closed trace with a rectangular cross section. To apply these equations for an IC inductor, the inductor is divided into many concentric thin wires of diameter da. Then, integrating from the internal radius a1 to the external radius a2 as shown in FIG. 7.

In FIG. 7, g(a) represents the current density function. Due to the skin effect, the current density is increased at edges of the rectangular conductor. For frequencies of interest, quasi-static density function g(a) is appropriate. The density function can be approximated by a sixth order polynomial function as shown in FIG. 7. Using the magnetic field, B, the magnetic flux is represented by:

$${Φ}_{0} = {\int }_{S} \vec{B} d \vec{S}$$

in turn the inductance of the inductor

$${L}_{0} = {Φ}_{0} / I$$

in free space void of any metallic objects. The proximity of metallic case of the crystal oscillator reduces inductance of the inductor because AC magnetic field will induce eddy currents in the crystal oscillator metal case and these currents will in turn generate AC magnetic field in opposite direction.

To calculate the effect of the metal case of a crystal resonator at distance d from the current loop, one may consider the mirror image. In that technique, the metal case is replaced with a second current loop at a distance 2d from the original current loop and having an opposite current direction. This provides a calculation for the reduction of the magnetic field in the original current and the reduced inductance.

$${Φ}_{0} = 2 π {{\int }_{{a}_{1}}^{{a}_{2}}}_{S} {B}_{z = 0} rdr$$

$${Φ}_{2 d} = 2 π {{\int }_{{a}_{1}}^{{a}_{2}}}_{S} {B}_{z = 2 d} rdr$$

$$Φ = {Φ}_{0} - {Φ}_{2 d}$$

$$L = \frac{Φ}{I}$$

This provides a formula for magnetic flux as a function of d. With this, there is a model for the reduction of inductance based on thickness of the spacer. In some arrangements, setting the thickness d equal to the diameter of the inductor provides an effective separation. The inductance change may be measured indirectly by measuring the change of the LC tank frequency as distance d between inductor and crystal.

$$f = \frac{1}{2 π \sqrt{LC}}$$

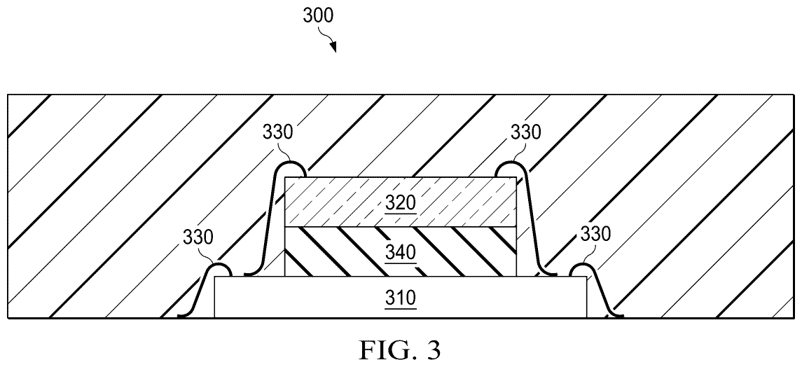

FIG. 3 shows an example IC package 300 incorporating teachings of the present disclosure including a silicon die 310 at the bottom, a non-conductive spacer 340, and a crystal 320 mounted on the spacer 340. The silicon die 310 and the crystal 320 are connected by bonding wires 330. The entire IC package 300 may be encapsulated.

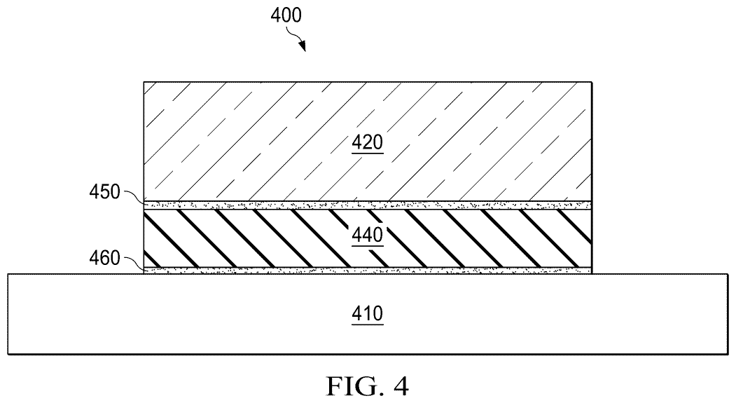

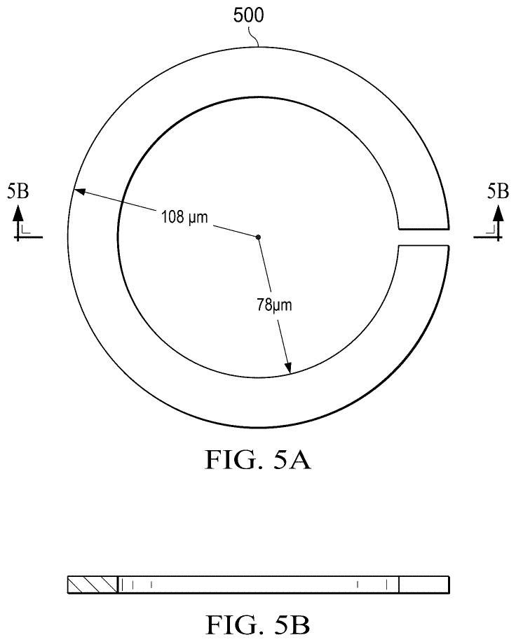

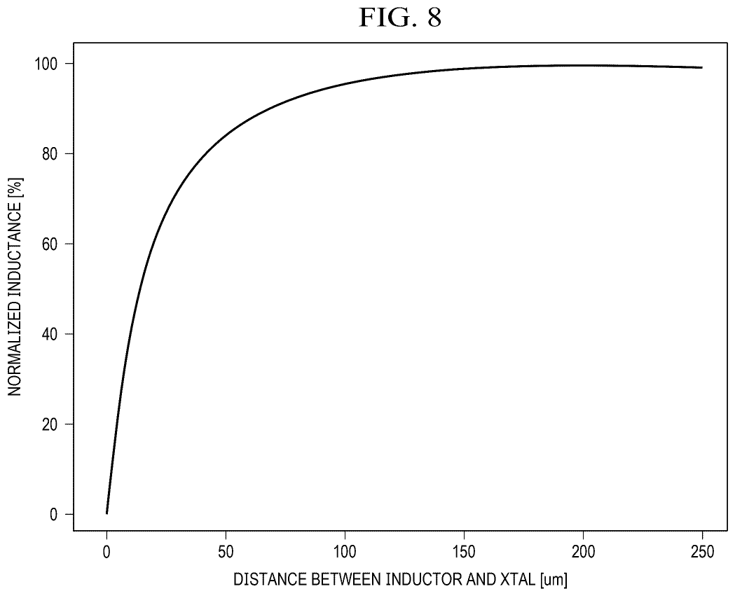

FIG. 4 shows an example IC package 400 incorporating teachings of the present disclosure including a silicon die 410 at the bottom, a non-conductive spacer 440, and a crystal 420 mounted on the spacer 440. The silicon die 410 and the crystal 420 are connected by bonding wires 430. The entire IC package 400 may be encapsulated. In the example shown, there is a layer of epoxy 450 providing a mechanical bond between the crystal 420 and the spacer 440. There is also a tape or a film 460 providing a mechanical bond between the silicon die 410 and the non-conductive spacer 440. FIGS. 5A-5B show a geometric equivalent of a rectangular trace-based inductor from a top view and a front view, respectively, for an example rectangular trace-based inductor 500. As shown in FIG. 5A, the inductor 500 has an effective internal diameter of 78 μm and an effective external diameter of 108 μm. Applying these values to the calculations described above provides: Then, for a rectangular trace-based inductor the resulting relationships between distance d and the reduction of the inductance are shown in FIG. 8.

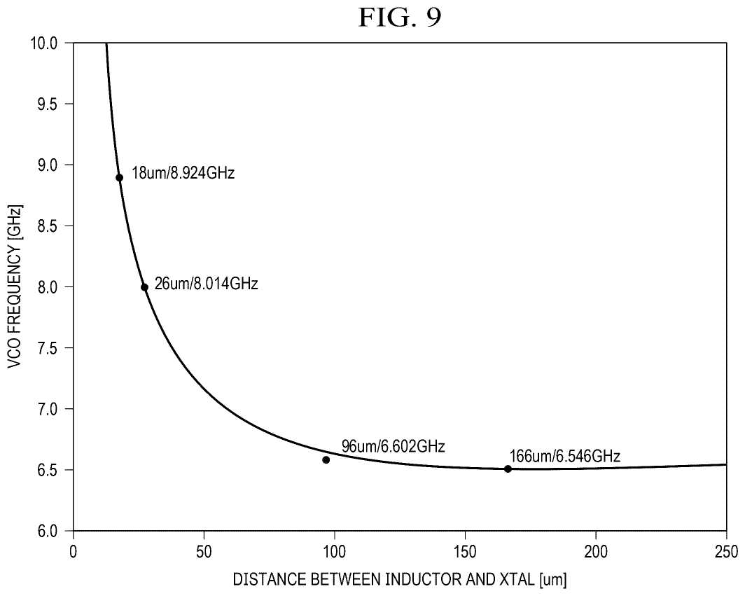

The VCO frequency versus the distance from the metal for uniform current distribution is shown in FIG. 9. The rectangular trace non-uniform current distribution demonstrates excellent matching between measurements (shown as discrete points) and the calculation (the trace). Based on these results, an appropriate thickness of the spacer is therefore substantially equal or equivalent to the equivalent diameter of the inductor. In this case, a value of about 200 μm. As shown in FIG. 4, the epoxy layer 450 and the tape or film 460 may each have a thickness of 18 μm.

We claim:

1. A system comprising:
a silicon die including an inductor element;
a crystal connected to the silicon die by bonding wires; and
a non-conductive spacer between the silicon die and the crystal;
wherein the non-conductive spacer has a thickness defining a distance between the silicon die and the crystal, the distance selected to reduce an effect of the crystal on a magnetic flux of the inductor element.

2. The system recited in claim 1, wherein the thickness is equivalent to an equivalent diameter of the inductor element.

3. The system recited in claim 1, wherein the inductor element includes a rectangular trace-based inductor.

4. The system recited in claim 1, wherein the crystal comprises an oscillator or a resonator.

5. The system recited in claim 1, wherein:
a footprint of the crystal is smaller than a footprint of the silicon die; and
a footprint of the system is constrained by the footprint of the silicon die but not the footprint of the crystal.

6. The system recited in claim 1, further comprising:
a film or tape between the silicon die and the non-conductive spacer; and
a layer of epoxy between the non-conductive spacer and the crystal.

7. An integrated circuit package comprising:
a silicon die including an inductor element;
a non-conductive spacer with a first side attached to the silicon die above the inductor element;
a crystal attached to a second side of the non-conductive spacer opposite the first side;
bonding wires connecting the crystal to the silicon die; and
an encapsulation surrounding the crystal and the non-conductive spacer;
wherein the non-conductive spacer has a thickness between the silicon die and the crystal, the thickness selected to reduce an effect of the crystal on a magnetic flux of the inductor element.

8. The integrated circuit package of claim 7, wherein the thickness is equivalent to an equivalent diameter of the inductor element.

9. The integrated circuit package of claim 7, wherein the inductor element includes a rectangular trace-based inductor.

10. The integrated circuit package of claim 7, wherein the crystal comprises an oscillator or a resonator.

11. The integrated circuit package of claim 7, wherein:
a footprint of the crystal is smaller than a footprint of the silicon die; and
a footprint of the integrated circuit package is constrained by the footprint of the silicon die but not the footprint of the crystal.

12. The integrated circuit package of claim 7, further comprising:
a tape or film between the silicon die and the non-conductive spacer; and
a layer of epoxy between the non-conductive spacer and the crystal.
